(19) United States
(12) Patent Application Publication
(10) Pub. No.: US 2019/0157429 A1
(43) Pub. Date: May 23, 2019

(54) BACK-CHANNEL-ETCHED TFT SUBSTRATE AND MANUFACTURING METHOD THEREOF

(71) Applicant: Shenzhen China Star Optoelectronics Semiconductor Display Technology Co., Ltd., Shenzhen City (CN)

(72) Inventor: Chunsheng Jiang, Shenzhen City (CN)

(21) Appl. No.: 15/749,095

(22) PCT Filed: Dec. 20, 2017
(86) PCT No.: PCT/CN2017/117306

§ 371 Date: Jan. 30, 2018

(30) Foreign Application Priority Data
Nov. 21, 2017 (CN) 201711167355.X

(51) Int. Cl. H01L 29/66; H01L 27/12; H01L 21/3213; H01L 29/45; H01L 29/786

(52) U.S. Cl. CPC H01L 29/66969; H01L 27/1262; H01L 29/7869; H01L 29/45; H01L 21/3213

(57) ABSTRACT

The invention provides a BCE TFT substrate and manufacturing method thereof. The manufacturing method of BCE TFT substrate of the invention uses C-axis crystallized IGZO thin film to fabricate the active layer. Because the C-axis crystallized IGZO has extremely high corrosion resistance and is resistant to the erosion of the copper etchant, the active layer is not damaged in the source/drain etching process, and the performance of the active layer is stable. The manufactured BCE TFT substrate has stable electric performance. The amorphous IGZO thin film for fabricating the C-axis crystallized IGZO thin film is prepared under high oxygen atmosphere, so that the crystallization annealing temperature of the amorphous IGZO thin film is reduced to 600° C. or below. A high-temperature annealing furnace is saved and the production cost reduced. The BCE TFT substrate of the invention manufactured by the above method has stable electric performance and low production cost.

### BACKGROUND OF THE INVENTION

### 1. Field of the Invention

The present invention relates to the field of display techniques, and in particular to a back-channel-etched thin film transistor (TFT) substrate and manufacturing method thereof.

### 2. The Related Arts

The liquid crystal display (LCD) provides advantages of thinness, low power-consumption and no radiation, and is widely used in, such as, LCD televisions, mobile phones, personal digital assistants (PDAs), digital cameras, computer screens, laptop screens, and so on.

Most of the LCDs on the current market are of backlight type, which comprises an LCD panel and a backlight module. The operation theory behind LCD is to inject the liquid crystal (LC) molecules between a thin film transistor (TFT) array substrate and a color filter (CF) substrate, and applies a driving voltage between the two substrates to control the rotation direction of the LC molecules to refract the light from the backlight module to generate the image on the display. The properties, features and operations of the TFT array substrate are mostly determined by the properties of the semiconductor elements forming the TFT array substrate.

The known TFT array substrate usually uses amorphous silicon (a-Si) to fabricate the semiconductor layer. However, with the development of the LCD device towards large size (75 inches or more) and high resolution (8K4K), and the use of copper (Cu) in the source and drain, the only about 1 cm²/(Vs) mobility of the conventional a-Si has been unable to meet the requirements, while the metal oxide material, such as, indium gallium zinc oxide (IGZO) with the more than 15 cm²/(Vs) mobility, and the corresponding TFT fabrication compatibility with existing production line of a-Si semiconductors, has rapidly become the focus of research and development in recent years.

Compared to the conventional a-Si TFT, IGZO TFT provides the following advantages:

1. Improve the resolution of the display backplane: under the premise of guaranteeing the same transmittance, IGZO TFT display backplane resolution can be done more than 2 times of the a-Si TFT, as the carrier concentration of IGZO material is high and the mobility is high so as to reduce the size of the TFT, to ensure resolution improvement;

2. Reduce the energy consumption of the display device: compared to a-Si TFT and LTPS TFT, the leakage current of the IGZO TFT is less than 1 pA; the driving frequency is reduced from the original 30-50 Hz to 2-5 Hz, and can even reach 1 Hz through special process. Although the number of TFT driving times is reduced, the number still maintains the alignment of the LC molecules without affecting the quality of the image. As such, the power consumption of the display backplane is reduced. In addition, the high mobility of the IGZO semiconductor material enables the smaller size TFTs to provide sufficient charging ability and higher capacitance, and also improves the aperture ratio of the liquid crystal panel, the effective area of light penetration becomes larger, the same brightness can be achieved with fewer backplane components or low power consumption, and the energy consumption can be reduced;

3. By using intermittent driving, the influence of the noise of the LCD driving circuit on the touch screen detection circuit can be reduced, the higher sensitivity can be achieved, and even the tip of the ballpoint pen tip can respond. Moreover, the power can be cut off as the screen is not updated; therefore, the performance on the energy-saving performance is better.

Currently, the IGZO TFT generally adopts an etch stop layer (ESL) structure. The ESL can effectively protect the IGZO from being affected in the source/drain etching process, to ensure that TFT has excellent semiconductor properties. However, the manufacturing process of IGZO TFT with ESL structure is complicated and requires six photolithography processes, which is disabling for cost reduction. Therefore, the development of IGZO TFT with a back-channel-etched (BCE) structure with less photolithography processes is generally pursued.

The BCE-structured IGZO TFT is realized by removing the ESL while using copper to manufacture the source and drain to reduce the number of photolithography processes by 1. However, the known copper etching solution inevitably affects the active layer of the IGZO and causes a certain amount of etching to change the surface characteristics of the active layer of the IGZO so that the stability of the TFT substrate is deteriorated.

### SUMMARY OF THE INVENTION

The object of the present invention is to provide a manufacturing method of the back-channel-etched (BCE) TFT substrate, able to ensure the active layer not damaged in the source/drain etching process, ensure the stable properties of the active layer, and ensure the stable electric properties of the manufactured BCE TFT substrate, while keeping production cost low.

Another object of the present invention is to provide a BCE TFT substrate, with stable electric properties and low production cost.

To achieve the above object, the present invention provides a manufacturing method of back-channel-etched TFT substrate, comprising:

providing a base substrate, forming a gate on the base substrate, forming a gate insulating layer on the gate and the base substrate;

forming a C-axis crystallized IGZO thin film on the gate insulating layer, patternizing the C-axis crystallized IGZO thin film to obtain an active layer;

forming a source and a drain separated with interval on the active layer.

According to a preferred embodiment of the present invention, the step of forming a C-axis crystallized IGZO thin film on the gate insulating layer comprises:

using a magnetron sputtering process to deposit an amorphous IGZO thin film on the gate insulating layer, during sputtering deposition, adding oxygen into the reaction chamber, and the volume percentage of oxygen in the total gas in the reaction chamber being greater than 40%, the molar ratio of indium, gallium, zinc, and oxide in the amorphous IGZO thin film being In:Ga:Zn:O=1:1:1:X, where X being greater than 4;

performing annealing on the amorphous IGZO thin film to obtain the C-axis crystallized IGZO thin film.

According to a preferred embodiment of the present invention, the molar ratio of indium, gallium, zinc, and oxide in the C-axis crystallized IGZO thin film is In:Ga:Zn:O=1:1:1:X, where X is greater than 4.

According to a preferred embodiment of the present invention, the annealing temperature of the annealing process on the amorphous IGZO thin film is less than or equal to 600° C.

According to a preferred embodiment of the present invention, the material of the source and the drain comprises copper.

The present invention also provides a back-channel-etched TFT substrate, comprising: a base substrate, a gate disposed on the base substrate, a gate insulating layer disposed on the gate and the base substrate, an active layer disposed on the gate insulating layer, and a source and a drain separated with interval on the active layer; wherein the active layer being a C-axis crystallized IGZO thin film.

According to a preferred embodiment of the present invention, the molar ratio of indium, gallium, zinc, and oxide in the C-axis crystallized IGZO thin film is In:Ga:Zn:O=1:1:1:X, where X is greater than 4.

According to a preferred embodiment of the present invention, the material of the source and the drain comprises copper.

The present invention also provides a manufacturing method of back-channel-etched TFT substrate, comprising:

providing a base substrate, forming a gate on the base substrate, forming a gate insulating layer on the gate and the base substrate;

forming a C-axis crystallized IGZO thin film on the gate insulating layer, patternizing the C-axis crystallized IGZO thin film to obtain an active layer;

forming a source and a drain separated with interval on the active layer.

wherein the step of forming a C-axis crystallized IGZO thin film on the gate insulating layer comprising:

using a magnetron sputtering process to deposit an amorphous IGZO thin film on the gate insulating layer, during sputtering deposition, adding oxygen into the reaction chamber, and the volume percentage of oxygen in the total gas in the reaction chamber being greater than 40%, the molar ratio of indium, gallium, zinc, and oxide in the amorphous IGZO thin film being In:Ga:Zn:O=1:1:1:X, where X being greater than 4;

performing annealing on the amorphous IGZO thin film to obtain the C-axis crystallized IGZO thin film;

wherein the molar ratio of indium, gallium, zinc, and oxide in the C-axis crystallized IGZO thin film being In:Ga:Zn:O=1:1:1:X, where X being greater than 4;

wherein the annealing temperature of the annealing process on the amorphous IGZO thin film being less than or equal to 600° C.;

wherein the material of the source and the drain comprising copper.

The present invention provides the following advantages. In the manufacturing method of BCE TFT substrate of the present invention, the C-axis crystallized IGZO thin film is used to fabricate the active layer. Because the C-axis crystallized IGZO has extremely high corrosion resistance and is resistant to the erosion of the copper etchant, the active layer is not damaged in the source/drain etching process, and the performance of the active layer is stable. The manufactured BCE TFT substrate has stable electric performance. In addition, the amorphous IGZO thin film for fabricating the C-axis crystallized IGZO thin film is prepared under a high oxygen atmosphere, so that the crystallization annealing temperature of the amorphous IGZO thin film is reduced to 600° C. or below. A high-temperature annealing furnace is saved and the production cost reduced. The BCE TFT substrate of the invention is manufactured by the above method, has stable electric performance and low production cost.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing a flowchart of the manufacturing method of BCE TFT substrate provided by an embodiment of the present invention;

FIG. 2 is a schematic view showing Step S1 of the manufacturing method of the BCE TFT substrate provided by an embodiment of the present invention;

FIG. 3 is a schematic view showing Step S2 of the manufacturing method of the BCE TFT substrate provided by an embodiment of the present invention;

FIG. 4 is a schematic view showing Step S3 of the manufacturing method of the BCE TFT substrate and structure of the BCE TFT substrate provided by an embodiment of the present invention.

### DETAILED DESCRIPTION OF THE PREFERRED EMBODIMENTS

To further explain the technique means and effect of the present invention, the following uses preferred embodiments and drawings for detailed description.

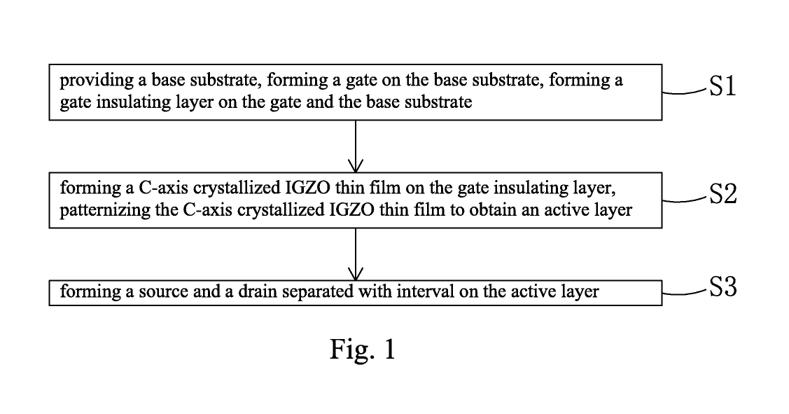

Referring to FIG. 1, the present invention provides a manufacturing method of back-channel-etched TFT substrate, comprising:

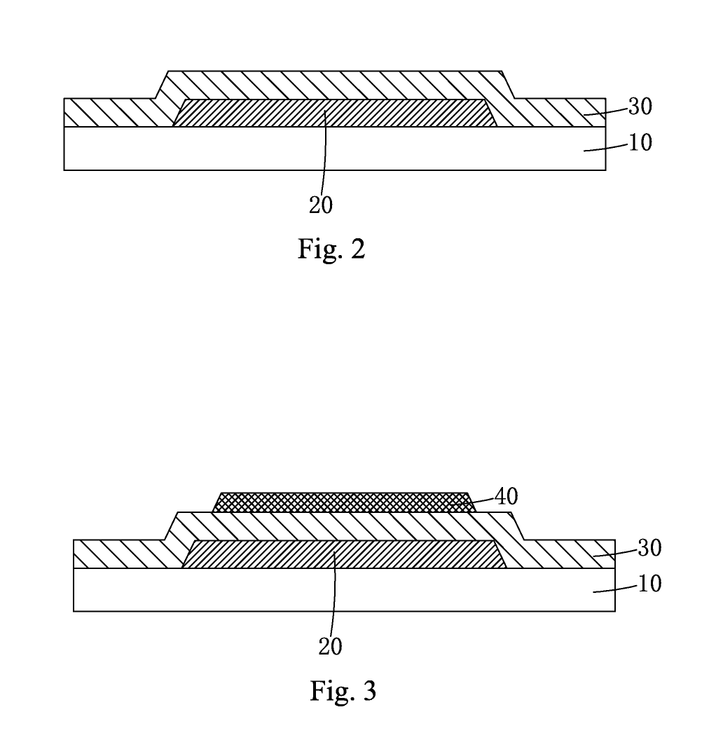

Step S1: as shown in FIG. 2, providing a base substrate 10, forming a gate 20 on the base substrate 10, forming a gate insulating layer 30 on the gate 20 and the base substrate 10.

Specifically, the base substrate 10 is a glass substrate.

Specifically, the materials for the gate 20 comprise one or more of the following: Mo, Al, Cu, Ti, and Cr.

Specifically, the step of forming the gate 20 on the base substrate 10 comprises: depositing a first metal thin film on the base substrate 10, using a photo-etching process to patternize the first metal thin film to obtain the gate 20.

Specifically, the gate insulating layer 30 is an SiOₓ, layer, a SiNₓ, layer, or a complex layer formed by stacking SiOₓ, layer and SiNₓ, layer.

Specifically, the gate insulating layer 30 is obtained by a chemical vapor deposition (CVD) process.

Step S2: forming a C-axis crystallized IGZO thin film on the gate insulating layer 30, patternizing the C-axis crystallized IGZO thin film to obtain an active layer 40.

Specifically, the step of forming a C-axis crystallized IGZO thin film on the gate insulating layer 30 comprises:

using a magnetron sputtering process to deposit an amorphous IGZO thin film on the gate insulating layer 30, during sputtering deposition, adding oxygen into the reaction chamber, and the volume percentage of oxygen in the total gas in the reaction chamber being greater than 40%, the molar ratio of indium, gallium, zinc, and oxide in the amorphous IGZO thin film being In:Ga:Zn:O=1:1:1:X, where X being greater than 4;

performing annealing on the amorphous IGZO thin film to obtain the C-axis crystallized IGZO thin film.

Specifically, in the process of sputtering deposition of amorphous IGZO thin film, the gas inside the reaction chamber comprises oxygen and argon.

During the process of sputtering deposition of amorphous IGZO thin films, the oxygen plays an important role in increasing the oxygen content in the amorphous IGZO thin film. Normally, the oxygen content in the reaction chamber is 5%-20% (by volume) and the molar ratio of In:Ga:Zn:O in the obtained amorphous IGZO thin film is In:Ga:Zn:O=1:1:1:4. The present invention increases the oxygen content in the amorphous IGZO thin film by increasing volume percentage of oxygen in the reaction chamber so that the molar ratio of indium gallium zinc oxide in the amorphous IGZO thin film is In:Ga:Zn:O=1:1:1:X, wherein X is larger than 4. Therefore, after annealing, the molar ratio of In:Ga:Zn:O of the obtained C-axis crystallized IGZO thin film is In:Ga:Zn:O=1:1:1:X, where X is greater than four.

Because of the high oxygen content of amorphous IGZO thin film, the high oxygen content can effectively ensure the oxygen demand of In/Ga/Zn bond breaking during amorphous IGZO crystallization and reduce the annealing temperature during subsequent crystallization annealing.

Specifically, the annealing temperature of the annealing process on the amorphous IGZO thin film is less than or equal to 600° C.

At present, the oxygen content in amorphous IGZO (a-IGZO) is 5%-20% (by volume) of the whole gas, and the amorphous IGZO film obtained under this oxygen content condition has a crystallization temperature as high as 1200° C. or higher. However, in the present invention, the crystallization annealing temperature of the deposited amorphous IGZO thin film can be decreased to 600° C. or lower under the condition that the oxygen content is greater than 40% by volume, which saves the use of a high-temperature annealing furnace and reduces the production cost.

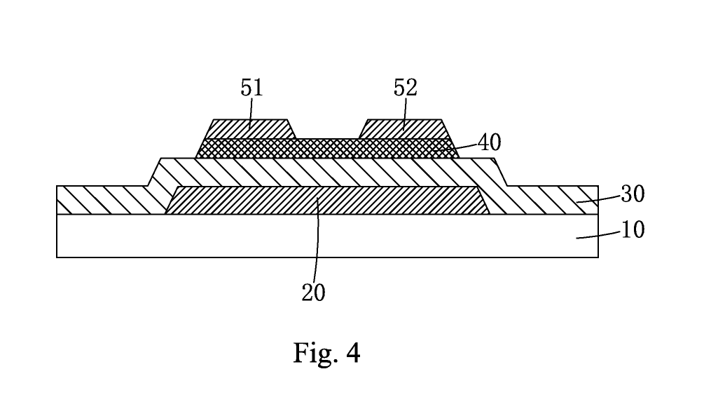

Step S3: as shown in FIG. 4, forming a source 51 and a drain 52 separated with interval on the active layer 40.

Specifically, the material of the source 51 and the drain 52 comprises copper. Because the active layer 40 is made of C-axis crystallized IGZO, which has extremely high corrosion resistance and is resistant to the erosion of the copper etchant, the active layer 40 is not damaged in the source 51 and drain 52 etching process, and the performance of the active layer 40 is stable. The manufactured BCE TFT substrate has stable electric performance.

Optionally, the materials of the source 51 and the drain 52 further comprise one or more of the following: Mo, Al, Ti, and Cr.

Specifically, the step of forming the source 51 and the drain 52 separated with interval on the active layer 40 comprises: depositing a second metal thin film on the active layer 40 and the gate insulating layer 30, using a photo-etching process to patternize the second metal thin film to obtain the source 51 and the drain 52 separated with interval on the active layer 40.

In the manufacturing method of BCE TFT substrate of the present invention, the C-axis crystallized IGZO thin film is used to fabricate the active layer 40. Because the C-axis crystallized IGZO has extremely high corrosion resistance and is resistant to the erosion of the copper etchant, the active layer is not damaged in the source 51 and drain 52 etching process, and the performance of the active layer 40 is stable. The manufactured BCE TFT substrate has stable electric performance. In addition, the amorphous IGZO thin film for fabricating the C-axis crystallized IGZO thin film is prepared under a high oxygen atmosphere, so that the crystallization annealing temperature of the amorphous IGZO thin film is reduced to 600° C. or below. A high-temperature annealing furnace is saved and the production cost reduced.

Refer to FIG. 4. Based on the above manufacturing method of BCE TFT substrate, the present invention also provides a BCE TFT substrate, comprising: a base substrate 10, a gate 20 disposed on the base substrate 10, a gate insulating layer 30 disposed on the gate 20 and the base substrate 10, an active layer 40 disposed on the gate insulating layer 30, and a source 51 and a drain 52 separated with interval on the active layer 40; wherein the active layer 40 being a C-axis crystallized IGZO thin film.

Specifically, the molar ratio of indium, gallium, zinc, and oxide in the C-axis crystallized IGZO thin film is In:Ga:Zn:O=1:1:1:X, where X is greater than 4.

Specifically, the material of the source 51 and the drain 52 comprises copper.

Optionally, the materials of the source 51 and the drain 52 further comprise one or more of the following: Mo, Al, Ti, and Cr.

Specifically, the base substrate 10 is a glass substrate.

Specifically, the gate insulating layer 30 is an SiOₓ layer, a SiNₓ layer, or a complex layer formed by stacking SiOₓ layer and SiNₓ layer.

The BCE TFT substrate of the present invention uses the C-axis crystallized IGZO thin film to fabricate the active layer 40. Because the C-axis crystallized IGZO has extremely high corrosion resistance and is resistant to the erosion of the copper etchant, the manufactured BCE TFT substrate has stable electric performance. In addition, the amorphous IGZO thin film for fabricating the C-axis crystallized IGZO thin film is prepared under a high oxygen atmosphere, so that the crystallization annealing temperature of the amorphous IGZO thin film is reduced. A high-temperature annealing furnace is saved and the production cost reduced.

In summary, the present invention provides a BCE TFT substrate and manufacturing method thereof. In the manufacturing method of BCE TFT substrate of the present invention, the C-axis crystallized IGZO thin film is used to fabricate the active layer. Because the C-axis crystallized IGZO has extremely high corrosion resistance and is resistant to the erosion of the copper etchant, the active layer is not damaged in the source/drain etching process, and the performance of the active layer is stable. The manufactured BCE TFT substrate has stable electric performance. In addition, the amorphous IGZO thin film for fabricating the C-axis crystallized IGZO thin film is prepared under a high oxygen atmosphere, so that the crystallization annealing temperature of the amorphous IGZO thin film is reduced to 600° C. or below. A high-temperature annealing furnace is saved and the production cost reduced. The BCE TFT substrate of the invention is manufactured by the above method, has stable electric performance and low production cost.

It should be noted that in the present disclosure the terms, such as, first, second are only for distinguishing an entity or operation from another entity or operation, and does not imply any specific relation or order between the entities or operations. Also, the terms “comprises”, “include”, and other similar variations, do not exclude the inclusion of other non-listed elements. Without further restrictions, the expression “comprises a . . . ” does not exclude other identical elements from presence besides the listed elements.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

1. A manufacturing method of back-channel-etched (BCE) thin film transistor (TFT) substrate, comprising:
providing a base substrate, forming a gate on the base substrate, forming a gate insulating layer on the gate and the base substrate;
forming a C-axis crystallized IGZO thin film on the gate insulating layer, patternizing the C-axis crystallized IGZO thin film to obtain an active layer;
forming a source and a drain separated with interval on the active layer,
wherein the C-axis crystallized IGZO thin film is formed on the gate insulating layer by using a sputtering process in a predetermined atmosphere including a gas that is a mixture of oxygen and argon to deposit an amorphous IGZO thin film on the gate insulating layer, followed by annealing of the amorphous IGZO thin film to obtain the C-axis crystallized IGZO thin film, wherein a volume percentage of oxygen in the gas of the mixture of oxygen and argon is greater than 40%.

2. The manufacturing method of BCE TFT substrate as claimed in claim 1, wherein
the sputtering process comprises a magnetron sputtering process, and oxide in the amorphous IGZO thin film deposited with the sputtering process is In:Ga:Zn:O=1:1:1:X, where X is greater than 4.

3. The manufacturing method of BCE TFT substrate as claimed in claim 1, wherein the molar ratio of indium, gallium, zinc, and oxide in the C-axis crystallized IGZO thin film is In:Ga:Zn:O=1:1:1:X, where X is greater than 4.

4. The manufacturing method of BCE TFT substrate as claimed in claim 1, wherein the annealing temperature of the annealing process on the amorphous IGZO thin film is less than or equal to 600° C.

5. The manufacturing method of BCE TFT substrate as claimed in claim 1, wherein the material of the source and the drain comprises copper.

6. A back-channel-etched (BCE) thin film transistor (TFT) substrate, comprising: a base substrate, a gate disposed on the base substrate, a gate insulating layer disposed on the gate and the base substrate, an active layer disposed on the gate insulating layer, and a source and a drain separated with interval on the active layer; wherein the active layer being a C-axis crystallized IGZO thin film.

7. The BCE TFT substrate as claimed in claim 6, wherein the molar ratio of indium, gallium, zinc, and oxide in the C-axis crystallized IGZO thin film is In:Ga:Zn:O=1:1:1:X, where X is greater than 4.

8. The BCE TFT substrate as claimed in claim 6, wherein the material of the source and the drain comprises copper.

9. A manufacturing method of back-channel-etched (BCE) thin film transistor (TFT) substrate, comprising:
providing a base substrate, forming a gate on the base substrate, forming a gate insulating layer on the gate and the base substrate;
forming a C-axis crystallized IGZO thin film on the gate insulating layer, patternizing the C-axis crystallized IGZO thin film to obtain an active layer;
forming a source and a drain separated with interval on the active layer;
wherein the C-axis crystallized IGZO thin film is formed on the gate insulating layer by using a sputtering process in a predetermined atmosphere including a gas that is a mixture of oxygen and argon to deposit an amorphous IGZO thin film on the gate insulating layer, followed by annealing of the amorphous IGZO thin film to obtain the C-axis crystallized IGZO thin film, wherein a volume percentage of oxygen in the gas of the mixture of oxygen and argon is greater than 40%;
wherein the sputtering process comprises a magnetron sputtering process, and oxide in the amorphous IGZO thin film deposited with the sputtering process is In:Ga:Zn:O=1:1:1:X, where X is greater than 4;
wherein the molar ratio of indium, gallium, zinc, and oxide in the C-axis crystallized IGZO thin film beings In:Ga:Zn:O=1:1:1:X, where X being greater than 4;
wherein the annealing temperature of the annealing process on the amorphous IGZO thin film being less than or equal to 600° C.;
wherein the material of the source and the drain comprising copper.
